(19) United States
(12) Patent Application Publication
(10) Pub. No.: US 2024/0339976 A1
(43) Pub. Date: Oct. 10, 2024

(54) RAIL-TO-RAIL INPUT STAGE CIRCUIT AND OPERATIONAL AMPLIFIER

(71) Applicant: Nuvoton Technology Corporation, Hsinchu Science Park (TW)

(72) Inventor: Cheng-Tao LI, Hsinchu Science Park (TW)

(21) Appl. No.: 18/401,468

(22) Filed: Dec. 30, 2023

(30) Foreign Application Priority Data
Apr. 7, 2023 (TW) 112112981

(51) Int. Cl. H03F 3/45; H03F 1/02; H03F 1/08

(52) U.S. Cl. CPC H03F 3/45183; H03F 1/0216; H03F 1/086; H03F 3/45273

(57) ABSTRACT

A rail-to-rail input stage circuit including a first P-type transistor, a second P-type transistor, a first N-type transistor, a second N-type transistor, a first processing circuit, a second processing circuit, a first voltage adjustment circuit, and a second voltage adjustment circuit is provided. The first P-type transistor and the first N-type transistor are coupled to a first input terminal. The second P-type transistor and the second N-type transistor are coupled to a second input terminal. In response to the voltage of the first terminal being higher than a first threshold value, the first voltage adjustment circuit controls the operation of the first processing circuit. In response to the voltage of the first terminal being lower than a second threshold value, the second voltage adjustment circuit controls the operation of the second processing circuit.

### CROSS REFERENCE TO RELATED APPLICATIONS

This application claims priority of Taiwan Patent Application No. 112112981, filed on Apr. 7, 2023, the entirety of which is incorporated by reference herein.

### BACKGROUND OF THE INVENTION

### Field of the Invention

The present invention relates to an input stage circuit, and, in particular, to the input stage circuit of an operational amplifier.

### Description of the Related Art

The operational amplifier is a common element. To obtain a high swing in a full voltage range, the operational amplifier needs to process an input voltage in the common mode of a rail-to-rail circuit. When receiving different input voltages, the gain of the operational amplifier must be maintained at a fixed value to ensure the efficiency of the operational amplifier.

### BRIEF SUMMARY OF THE INVENTION

In accordance with an embodiment of the disclosure, a rail-to-rail input stage circuit is coupled to an output stage circuit. The output stage circuit comprises an output terminal. The voltage level of the output terminal is related to the voltage levels of the first input terminal and the second input terminal. The rail-to-rail input stage circuit comprises a first current source, a second current source, a first P-type transistor, a second P-type transistor, a first N-type transistor, a second N-type transistor, a first processing circuit, a second processing circuit, a first voltage adjustment circuit, and a second voltage adjustment circuit. The first current source provides a first current. The second current source provides a second current. The first P-type transistor is coupled between the first current source and the output stage circuit and is coupled to the first input terminal. The second P-type transistor is coupled between the first current source and the output stage circuit and is coupled to the second input terminal. The first N-type transistor is coupled between the second current source and the output stage circuit and is coupled to the first input terminal. The second N-type transistor is coupled between the second current source and the output stage circuit and is coupled to the second input terminal. The first processing circuit generates a third current based on a first control voltage in response to the voltage level of the first input terminal being higher than a first threshold value. The sum of currents passing through the first N-type transistor and the second N-type transistor is equal to the sum of the first current and the third current. The second processing circuit generates a fourth current based on a second control voltage in response to the voltage level of the first input terminal being lower than a second threshold value. The sum of currents passing through the first P-type transistor and the second P-type transistor is equal to the sum of the second current and the fourth current. The first voltage adjustment circuit adjusts the first control voltage in response to the voltage level of the first input terminal being higher than the first threshold value. The second voltage adjustment circuit adjusts the second control voltage in response to the voltage level of the first input terminal being lower than the second threshold value.

In accordance with another embodiment of the disclosure, an operational amplifier comprises an input stage circuit and an output stage circuit. The input stage circuit comprises a first current source, a second current source, a first P-type transistor, a second P-type transistor, a first N-type transistor, a second N-type transistor, a first processing circuit, a second processing circuit, a first voltage adjustment circuit, and a second voltage adjustment circuit. The first current source provides a first current. The second current source provides a second current. The first P-type transistor is coupled between the first current source and a first node and is coupled to a first input terminal. The second P-type transistor is coupled between the first current source and a second node and is coupled to a second input terminal. The first N-type transistor is coupled between the second current source and a third node and is coupled to the first input terminal. The second N-type transistor is coupled between the second current source and a fourth node and is coupled to the second input terminal. The first processing circuit generates a third current based on a first control voltage in response to the voltage level of the first input terminal being higher than a first threshold value. The sum of currents passing through the first transistor and the second N-type transistor is equal to the sum of the first current and the third current. The second processing circuit generates a fourth current based on a second control voltage in response to the voltage level of the first input terminal being lower than a second threshold value. The sum of currents passing through the first P-type transistor and the second P-type transistors is equal to the sum of the second current and the fourth current. The first voltage adjustment circuit adjusts the first control voltage in response to the voltage level of the first input terminal being higher than the first threshold value. The second voltage adjustment circuit adjusts the second control voltage in response to the voltage level of the first input terminal being lower than the second threshold value. The output stage circuit generates an output voltage based on the voltage levels of the first node, the second node, the third node, and the fourth node.

### BRIEF DESCRIPTION OF THE DRAWINGS

The present invention can be more fully understood by reading the subsequent detailed description and examples with references made to the accompanying drawings, wherein:

FIG. 1 is a schematic diagram of an exemplary embodiment of an operational amplifier according to various aspects of the present disclosure.

FIG. 2 is a schematic diagram of an exemplary embodiment of a voltage adjustment circuit according to various aspects of the present disclosure.

FIG. 3 is a schematic diagram of another exemplary embodiment of the voltage adjustment circuit according to various aspects of the present disclosure.

FIG. 4 is a schematic diagram of an exemplary embodiment of an input stage circuit according to various aspects of the present disclosure.

### DETAILED DESCRIPTION OF THE INVENTION

The present invention will be described with respect to particular embodiments and with reference to certain drawings, but the invention is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the invention.

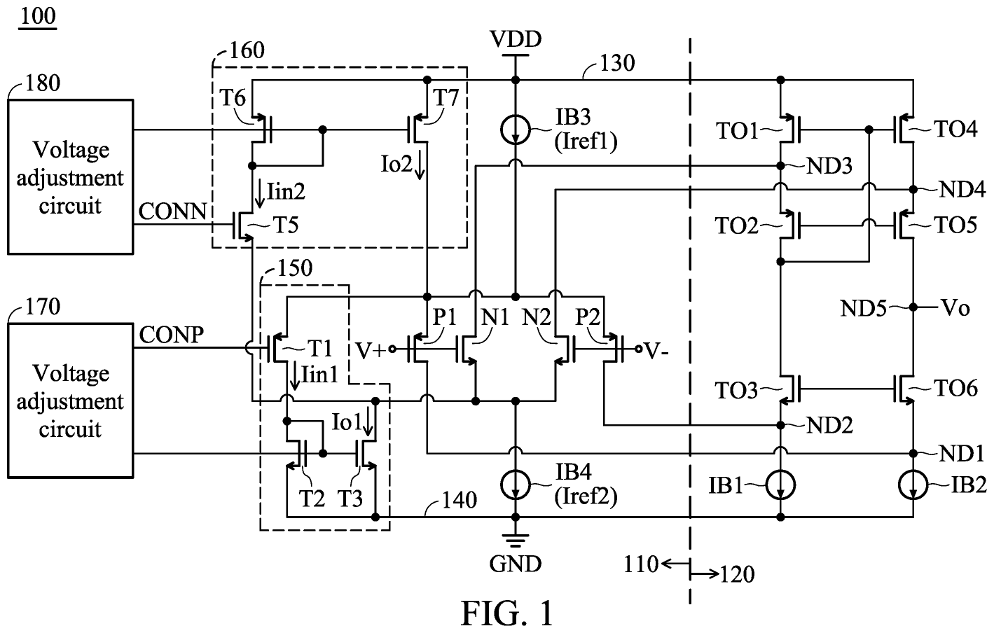

FIG. 1 is a schematic diagram of an exemplary embodiment of an operational amplifier according to various aspects of the present disclosure. The operational amplifier 100 is coupled between the power rails 130 and 140 and comprises an input stage circuit 110 and an output stage circuit 120. The input stage circuit 110 and the output stage circuit 120 are coupled between the power rails 130 and 140. In this embodiment, the power rail 130 receives an operation voltage VDD. The power rail 140 receives a ground voltage GND. In this case, the operation voltage VDD is higher than the ground voltage GND. For example, the operation voltage VDD is about 5V, and the ground voltage GND is about 0V.

The input stage circuit 110 is coupled between the power rails 130 and 140. Therefore, the input stage circuit 110 is referred to as a rail-to-rail input stage circuit. In this embodiment, the input stage circuit 110 comprises current sources IB3 and IB4, P-type transistors P1 and P2, N-type transistors N1 and N2, processing circuits 150 and 160, and voltage adjustment circuits 170 and 180.

The current source IB3 provides a current Iref1. The current source IB4 provides a current Iref2. In one embodiment, the current Iref1 is about equal to the current Iref2. In this embodiment, the current source IB3 is coupled between the power rail 130 and the source of the P-type transistor P1. The current source IB4 is coupled between the source of the N-type transistor N1 and the power rail 140.

The P-type transistor P1 is coupled between the current source IB3 and the node ND1 and coupled to the input terminal V+. In this embodiment, the source of the P-type transistor P1 is coupled to the current source IB3. The drain of the P-type transistor P1 is coupled to the node ND1. The gate of the P-type transistor P1 is coupled to the input terminal V+.

The P-type transistor P2 is coupled between the current source IB3 and the node ND2 and coupled to the input terminal V−. In this embodiment, the source of the P-type transistor P2 is coupled to the current source IB3. The drain of the P-type transistor P2 is coupled to the node ND2. The gate of the P-type transistor P2 is coupled to the input terminal V−.

The N-type transistor N1 is coupled between the current source IB4 and the node ND3 and coupled to the input terminal V+. In this embodiment, the source of the N-type transistor N1 is coupled to the current source IB4. The drain of the N-type transistor N1 is coupled to the node ND3. The gate of the N-type transistor N1 is coupled to the input terminal V+.

The N-type transistor N2 is coupled between the current source IB4 and the node ND4 and coupled to the input terminal V−. In this embodiment, the source of the N-type transistor N2 is coupled to the current source IB4. The drain of the N-type transistor N2 is coupled to the node ND4. The gate of the N-type transistor N2 is coupled to the input terminal V−.

The processing circuit 150 is coupled to the current source IB3. When the voltage level of the input terminal V+ is gradually increased (e.g., from 0V to 5V), the P-type transistors P1 and P2 are gradually turned off. Therefore, the currents passing through the P-type transistors P1 and P2 are gradually reduced. When the voltage level of the input terminal V+ is higher than a first threshold value, a portion of the current Iref1 passes through the processing circuit 150. The processing circuit 150 generates a current Io1 based on a control voltage CONP. In this embodiment, when the voltage level of the input terminal V+ is higher than a first threshold value, the sum of the currents passing through the N-type transistors N1 and N2 is equal to the sum of the currents Iref1 and Io1. In one embodiment, current Io1 is three times current Iref1. In some embodiments, the first threshold value is about the same as the difference between the voltage level of the power rail 130 and the threshold voltage of the P-type transistor P1.

The structure of processing circuit 150 is not limited in the present disclosure. In one embodiment, the processing circuit 150 comprises transistors T1˜T3. In this case, the transistor T1 is a P-type transistor, and the transistors T2 and T3 are N-type transistors. In one embodiment, the transistor T1 is referred to as a compensation transistor to compensate the effect caused by the P-type transistors P1 and P2 which are not turned on. Therefore, the gain (gm) of the operational amplifier 100 is maintained. As shown in FIG. 1, the source of the transistor T1 is coupled to the current source IB3. The drain of the transistor T1 is coupled to the drain of the transistor T2. The gate of the transistor T1 receives the control voltage CONP.

The drain and the gate of the transistor T2 are coupled to the drain of the transistor T1. The source of the transistor T2 is coupled to the power rail 140. The gate of the transistor T3 is coupled to the gate of the transistor T2. The drain of the transistor T3 is coupled to the source of the N-type transistor N1. The source of the transistor T3 is coupled to the power rail 140. In this embodiment, the transistors T2 and T3 constitute a current mirror. When the current passing through the transistor T1 enters the transistor T2, the current Io1 (referred to as a third current) passes through the transistor T3. In one embodiment, the current Io1 is three times current Iin1. In some embodiments, the size of the channel of the transistor T3 is three times the size of the channel of the transistor T2.

The processing circuit 160 is coupled to the current source IB4. When the voltage level of the input terminal V− is gradually reduced (e.g., from 5V to 0V), the N-type transistors N1 and N2 are gradually turned off. When the voltage level of the input terminal V− is lower than a second threshold value, the processing circuit 160 generates a current Io2 based on a control voltage CONN. In one embodiment, the second threshold value is lower than the first threshold value. In some embodiments, the second threshold value is about equal to the threshold voltage of the N-type transistor N1. In this embodiment, when the voltage level of the input terminal V1 is lower than the second threshold value, the sum of the currents passing through the P-type transistors P1 and P2 is equal to the sum of the currents Iref2 and Io2. In one embodiment, current Io2 is three times current Iref2.

The structure of processing circuit 160 is not limited in the present disclosure. In one embodiment, the processing circuit 160 comprises transistors T5˜T7. In this case, the transistor T5 is a N-type transistor, and the transistors T6 and T7 are P-type transistors. In one embodiment, the transistor T5 is referred to as a compensation transistor to compensate the effect caused by the N-type transistors N1 and N2 which are not turned on. Therefore, the gain of the operational amplifier 100 is maintained. As shown in FIG. 1, the source of the transistor T5 is coupled to the current source IB4. The drain of the transistor T5 is coupled to the drain of the transistor T6. The gate of the transistor T5 receives the control voltage CONN.

The drain and the gate of the transistor T6 are coupled to the drain of the transistor T5. The source of the transistor T6 is coupled to the power rail 130. The gate of the transistor T7 is coupled to the gate of the transistor T6. The drain of the transistor T7 is coupled to the source of the P-type transistor P1. The source of the transistor T7 is coupled to the power rail 130. In this embodiment, the transistors T6 and T7 constitute another current mirror. When the current Iin2 passes through the transistor T6, the current Io2 passes through the transistor T7.

The voltage adjustment circuit 170 provides and adjusts the control voltage CONP. When the voltage level of the input terminal V+ is higher than a first threshold value, the voltage adjustment circuit 170 adjusts the control voltage CONP based on the current Iin1 passing through the transistor T1. In this embodiment, since the transistor T1 is a P-type transistor, when the voltage adjustment circuit 170 reduces the control voltage CONP, more current passes through the transistor T1. Therefore, the current Io1 quickly triples the current Iref1. The present disclosure does not limit how the voltage adjustment circuit 170 detects the current Iin1 passing through the transistor T1. In one embodiment, the voltage adjustment circuit 170 is coupled to the gate of the transistor T2. When the voltage of the gate of the transistor T2 is increased, this indicates that the P-type transistors P1 and P2 are gradually turned off such that a portion of current Iref1 enters the transistor T1. Therefore, the voltage adjustment circuit 170 reduces the control voltage CONP to increase the current Iin1 passing through the transistor T1.

The voltage adjustment circuit 180 adjusts the control voltage CONN based on the current Iin2 which passes through the transistor T5. When the voltage level of the input terminal V− is lower than a second threshold value, the voltage adjustment circuit 180 adjusts the control voltage CONN such that the current Iin2 quickly increases. Therefore, the current Io2 can quickly triple the current Iref2. In one embodiment, the voltage adjustment circuit 180 is coupled to the gate of the transistor T6. When the voltage of the gate of the transistor T6 is increased, this indicates that the N-type transistors N1 and N2 are gradually turned off. Therefore, the voltage adjustment circuit 180 increases the control voltage CONN to increase the current Iin2 passing through the transistor T5.

In some embodiments, when the voltage adjustment circuit 170 adjusts the voltage (i.e., the control voltage CONP) of the gate of the transistor T1, the voltage adjustment circuit 180 stops adjusting the voltage (i.e., the control voltage CONN) of the gate of the transistor T5. In this case, when the voltage adjustment circuit 180 adjusts the voltage (i.e., the control voltage CONN) of the gate of the transistor T5, the voltage adjustment circuit 170 stops adjusting the voltage (i.e., the control voltage CONP) of the gate of the transistor T1.

The output stage circuit 120 generates an output voltage Vo based on the voltage levels of the nodes ND1˜ND4. The structure of output stage circuit 120 is not limited in the present disclosure. In one embodiment, the output stage circuit 120 comprises output transistors TO1˜TO6 and current sources IB1 and IB2. The output transistors TO1, TO2, TO4, and TO5 are P-type transistors, and the output transistors TO3 and TO6 are N-type transistors.

The source of the output transistor TO1 is coupled to the power rail 130. The gate of the output transistor TO1 is coupled to the gate of the output transistor TO4. The drain of the output transistor TO1 is coupled to the node ND3. The source of the output transistor TO2 is coupled to the drain of the output transistor TO1. The gate of the output transistor TO2 is coupled to the gate of the output transistor TO5. The drain of the output transistor TO2 is coupled to the gate of the output transistor TO1. The drain of the output transistor TO3 is coupled to the drain of the output transistor TO2. The gate of the output transistor TO3 is coupled to the gate of the output transistor TO6. The source of the output transistor TO3 is coupled to the node ND2. The current source IB1 is coupled between the source of the output transistor TO3 and the power rail 130.

The source of the output transistor TO4 is coupled to the power rail 130. The gate of the output transistor TO4 is coupled to the gate of the output transistor TO1. The drain of the output transistor TO4 is coupled to the node ND4. The source of the output transistor TO5 is coupled to the drain of the output transistor TO4. The gate of the output transistor TO5 is coupled to the gate of the output transistor TO2. The drain of the output transistor TO5 is coupled to the node ND5. The node ND5 is served as an output terminal to provide the output voltage Vo. The drain of the output transistor TO6 is coupled to the drain of the output transistor TO5. The gate of the output transistor TO6 is coupled to the gate of the output transistor TO3. The source of the output transistor TO6 is coupled to the node ND1. The current source IB2 is coupled to the source of the output transistor TO6 and the power rail 140.

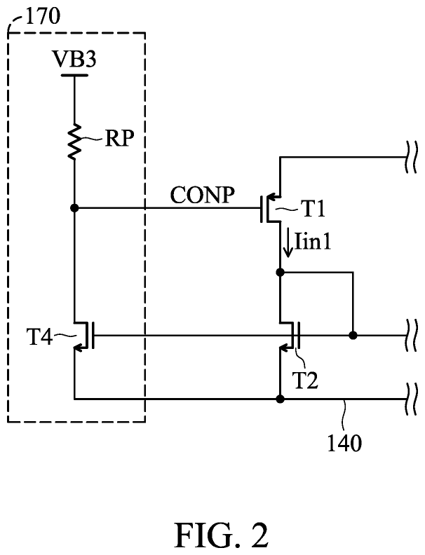

FIG. 2 is a schematic diagram of an exemplary embodiment of the voltage adjustment circuit 170 according to various aspects of the present disclosure. The voltage adjustment circuit 170 comprises an impedance element RP and a transistor T4. The impedance element RP is coupled between a voltage source VB3 and the gate of the transistor T1 and configured to provide the control voltage CONP. In one embodiment, the impedance element RP is a resistor. The transistor T4 is serially coupled to the impedance element RP and coupled to the gate of the transistor T2. In this embodiment, the transistor T4 is a N-type transistor. The gate of the transistor T4 is coupled to the gate of the transistor T2. The drain of the transistor T4 is coupled to the gate of the transistor T1 and the impedance element RP. The source of the transistor T4 is coupled to the power rail 140.

In some embodiments, the transistors T2 and T4 constitute a current mirror. In this case, when the current Iin1 enters the transistor T2, the transistor T4 is turned on. At this time, the current passing through the transistor T4 is about equal to the current Iin1. The impedance element RP generates a voltage drop to reduce the control voltage CONP. Therefore, the current Iin1 passing through the transistor T1 is increased.

For example, assume that the voltage level provided by the voltage source VB3 is 4V, the resistance of the impedance element RP is 40 KΩ, and the current Iin1 is 10 uA. In this case, when the current Iin1 enters the transistor T2, the current passing through the impedance element RP is equal to 10 uA. Therefore, the voltage drop of the impedance element RP is about 400 mA (40K×10u) so that the control voltage CONP reduces to 3.6V.

In one embodiment, the voltage level of the voltage source VB3 is equal to the first threshold value. In this case, when the voltage level of the input terminal V+ is increased and higher than the voltage level of the voltage source VB3, the current Iin1 enters the transistor T2. Therefore, the impedance element RP generates a voltage drop to reduce the control voltage CONP.

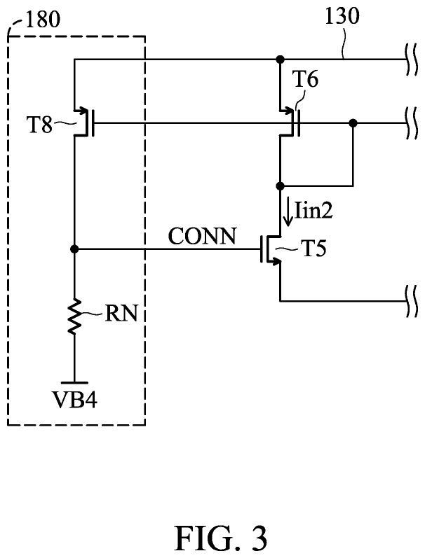

FIG. 3 is a schematic diagram of an exemplary embodiment of the voltage adjustment circuit 180 according to various aspects of the present disclosure. The voltage adjustment circuit 180 comprises an impedance element RN and a transistor T8. The impedance element RN is coupled between a voltage source VB4 and the gate of the transistor T5 and configured to provide the control voltage CONN. The voltage level of the voltage source VB4 may be lower than the voltage level of the voltage source VB3. In one embodiment, the impedance element RN is a resistor. In this case, the resistance of the impedance element RN is similar to the resistance of the impedance element RP.

The transistor T8 is serially coupled to the impedance element RN and coupled to the gate of the transistor T6. In this embodiment, the transistor T8 is a P-type transistor. The gate of the transistor T8 is coupled to the gate of the transistor T6. The drain of the transistor T8 is coupled to the gate of the transistor T5 and the impedance element RN. The source of the transistor T8 is coupled to the power rail 130.

In some embodiments, the transistors T6 and T8 constitute a current mirror. In this case, the current passing through the transistor T8 is about equal to the current Iin2 of the transistor T6. When a current enters the transistor T8, the impedance element RN causes a voltage rise. Therefore, the control voltage CONN is increased so that the current Iin2 increases. In one embodiment, the second threshold value is equal to the voltage level of the voltage source VB4.

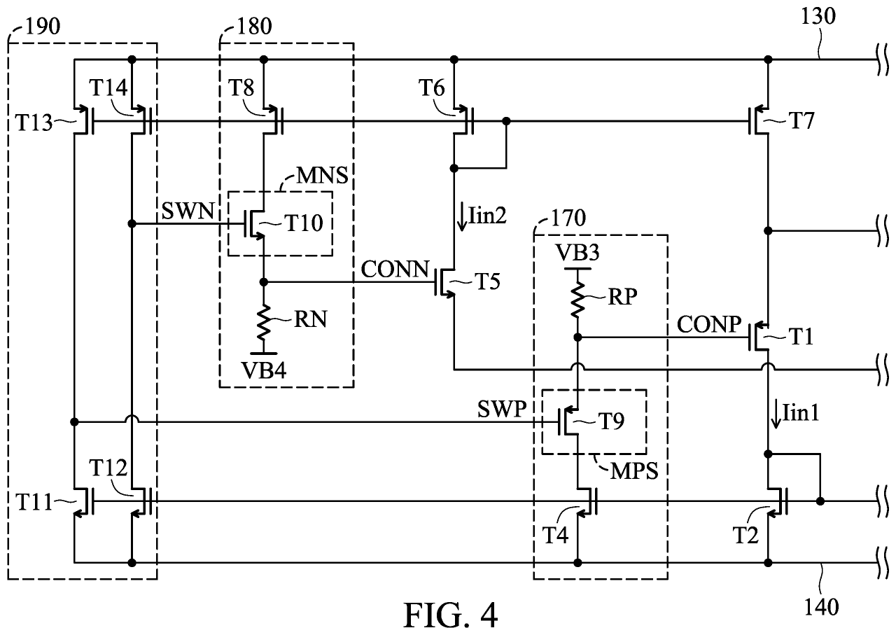

FIG. 4 is a schematic diagram of an exemplary embodiment of an input stage circuit according to various aspects of the present disclosure. Some elements which are shown in FIG. 1 are omitted. The input stage circuit comprises a control circuit 190, switches MPS and MNS. The switch MPS is coupled between the impedance element RP and the transistor T4 of the voltage adjustment circuit 170. In this embodiment, the switch MPS is a P-type transistor T9. The source of the P-type transistor T9 is coupled to the impedance element RP and the gate of the transistor T1. The drain of the P-type transistor T9 is coupled to the drain of the transistor T4. The gate of the P-type transistor T9 receives a switching signal SWP.

The switch MNS is coupled between the impedance element RN and the transistor T8 of the voltage adjustment circuit 180. In this embodiment, the switch MNS is a N-type transistor T10. The source of the N-type transistor T10 is coupled to the impedance element RN and the gate of the transistor T5. The drain of the N-type transistor T10 is coupled to the drain of the transistor T8. The gate of the N-type transistor T10 receives a.

The control circuit 190 controls the switching signals SWN and SWP to prevent the voltage adjustment circuits 170 and 180 from being turned on at the same time. For example, when a current (e.g., Iin1) passes through the transistor T1, the control circuit 190 turns on the switch MPS and turns off the switch MNS. However, a current (e.g., Iin2) passes through the transistor T5, the control circuit 190 turns on the switch MNS and turns off the switch MPS. In other embodiments, the control circuit 190 may turn off the switches MNS and MPS simultaneously.

The structure of control circuit 190 is not limited in the present disclosure. In this embodiment, the control circuit 190 comprises transistors T11˜T14. The transistors T11 and T12 are N-type transistors, and the transistors T13 and T14 are P-type transistors. In this case, the gate of the transistor T11 is coupled to the gate of the transistor T4. The source of the transistor T11 is coupled to the power rail 140. The drain of the transistor T11 is coupled to the gate of the transistor T9.

In one embodiment, the transistors T11 and T2 constitute a current mirror. When the current Iin1 enters the transistor T2, the transistor T11 is turned on so that the level of the switching signal SWP is equal to the voltage level (e.g., 0V) of the power rail 140. Therefore, the transistor T9 is turned on. Since the impedance element RP causes a voltage drop so that the current passing through the transistor T1 is increased and the current Io1 quickly reaches the target value (e.g., three times the current Iref1).

The gate of the transistor T12 is coupled to the gate of the transistor T4. The source of the transistor T12 is coupled to the power rail 140. The drain of the transistor T12 is coupled to the gate of the transistor T10. In one embodiment, the transistors T12 and T2 constitute a current mirror. When the current Iin1 enters the transistor T2, the transistor T12 is turned on so that the level of the switching signal SWN is equal to the voltage level (e.g., 0V) of the power rail 140. Therefore, the transistor T10 is turned off so that the transistor T5 is turned off.

The gate of the transistor T13 is coupled to the gate of the transistor T8. The source of the transistor T13 is coupled to the power rail 130. The drain of the transistor T13 is coupled to the gate of the transistor T9. In one embodiment, the transistors T13 and T6 constitute a current mirror. When the current Iin2 enters the transistor T6, the transistor T13 is turned on so that the level of the switching signal SWP is equal to the voltage level (e.g., 5V) of the power rail 130. Therefore, the transistor T19 is turned off.

The gate of the transistor T14 is coupled to the gate of the transistor T8. The source of the transistor T14 is coupled to the power rail 130. The drain of the transistor T14 is coupled to the gate of the transistor T10. In one embodiment, the transistors T14 and T6 constitute a current mirror. When the current Iin2 enters the transistor T6, the transistor T14 is turned on so that the level of the switching signal SWN is equal to the voltage level (e.g., 5V) of the power rail 130. Therefore, the transistor T10 is turned on. Since the impedance element RN causes a voltage rise so that the current passing through the transistor T5 is increased and the current Io2 quickly reaches the target value (e.g., three times the current Iref2).

It will be understood that when an element or layer is referred to as being “on”, “connected to” or “coupled to” another element or layer, it can be directly on, connected or coupled to the other element or layer or intervening elements or layers may be present. In contrast, when an element or layer is referred to as be “directly on”, “directly connected to” or “directly coupled to” another element or layer, there are no intervening elements or layers present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A rail-to-rail input stage circuit coupled to an output stage circuit comprising an output terminal whose voltage level is related to voltage levels of a first input terminal and a second input terminal, wherein the rail-to-rail input stage circuit comprises:
a first current source providing a first current;
a second current source providing a second current;
a first P-type transistor coupled between the first current source and the output stage circuit and coupled to the first input terminal;
a second P-type transistor coupled between the first current source and the output stage circuit and coupled to the second input terminal;
a first N-type transistor coupled between the second current source and the output stage circuit and coupled to the first input terminal;
a second N-type transistor coupled between the second current source and the output stage circuit and coupled to the second input terminal;
a first processing circuit generating a third current based on a first control voltage in response to the voltage level of the first input terminal being higher than a first threshold value, wherein a sum of currents passing through the first N-type transistor and the second N-type transistor is equal to a sum of the first current and the third current;
a second processing circuit generating a fourth current based on a second control voltage in response to the voltage level of the first input terminal being lower than a second threshold value, wherein a sum of currents passing through the first P-type transistor and the second P-type transistor is equal to a sum of the second current and the fourth current;
a first voltage adjustment circuit adjusting the first control voltage in response to the voltage level of the first input terminal being higher than the first threshold value; and
a second voltage adjustment circuit adjusting the second control voltage in response to the voltage level of the first input terminal being lower than the second threshold value.

2. The rail-to-rail input stage circuit as claimed in claim 1, wherein the first processing circuit comprises:
a first transistor coupled to the first current source; and
a first current mirror receiving the current passing through the first transistor, and generating the third current.

3. The rail-to-rail input stage circuit as claimed in claim 2, wherein:
the first current mirror comprises a second transistor and a third transistor,
the drain and the gate of the second transistor are coupled to the drain of the first transistor, the gate of the third transistor is coupled to the gate of the second transistor, and the drain of the third transistor is coupled to the first N-type transistor.

4. The rail-to-rail input stage circuit as claimed in claim 3, wherein the first voltage adjustment circuit comprises:
a first impedance element coupled between a first voltage source and the gate of the first transistor, and configured to provide the first control voltage; and
a fourth transistor coupled to the first impedance element in series and coupled to the gate of the second transistor,
wherein the current passing through the fourth transistor is equal to the current passing through the second transistor.

5. The rail-to-rail input stage circuit as claimed in claim 4, wherein the second processing circuit comprises:
a fifth transistor coupled to the second current source; and
a second current mirror generating the fourth current based on the current passing through the fifth transistor.

6. The rail-to-rail input stage circuit as claimed in claim 5, wherein the fourth current is equal to the third current.

7. The rail-to-rail input stage circuit as claimed in claim 5, wherein:
the second current mirror comprises a sixth transistor and a seventh transistor,
the drain and the gate of the sixth transistor are coupled to the drain of the fifth transistor, the gate of the seventh transistor is coupled to the gate of the sixth transistor, and the drain of the seventh transistor is coupled to the first P-type transistor.

8. The rail-to-rail input stage circuit as claimed in claim 7, wherein the second voltage adjustment circuit comprises:
a second impedance element coupled between a second voltage source and the gate of the fifth transistor, and configured to provide the second control voltage; and
an eighth transistor coupled to the second impedance element in series and coupled to the gate of the sixth transistor,
wherein the current passing through the eighth transistor is equal to the current passing through the fifth transistor.

9. The rail-to-rail input stage circuit as claimed in claim 8, further comprising:
a first switch coupled between the first impedance element and the fourth transistor;
a second switch coupled between the second impedance element and the eighth transistor; and
a control circuit controlling the first switch and the second switch.

10. The rail-to-rail input stage circuit as claimed in claim 9, wherein in response to the first current passing through the first transistor, the control circuit turns on the first switch, and in response to the second current passing through the fifth transistor, the control circuit turns on the second switch.

11. The rail-to-rail input stage circuit as claimed in claim 9, wherein in response to the first switch being turned on, the second switch is turned off, and in response to the first switching not being turned on, the second switch is turned on.

12. The rail-to-rail input stage circuit as claimed in claim 9, wherein:
the first switch is a ninth transistor,
the source of the ninth transistor is coupled to the gate of the first transistor, and the drain of the ninth transistor is coupled to the drain of the fourth transistor,
the second switch is a tenth transistor,
the source of the tenth transistor is coupled to the gate of the fifth transistor, and the drain of the tenth transistor is coupled to the drain of the eighth transistor.

13. The rail-to-rail input stage circuit as claimed in claim 12, wherein the control circuit comprises:
an eleventh transistor comprising:
a gate coupled to the gate of the fourth transistor; and
a drain coupled to the gate of the ninth transistor;
a twelfth transistor comprising:
a gate coupled to the gate of the fourth transistor; and
a drain coupled to the gate of the tenth transistor;
a thirteenth transistor comprising:
a gate coupled to the gate of the eighth transistor; and
a drain coupled to the gate of the ninth transistor; and
a fourteenth transistor comprising:
a gate coupled to the gate of the eighth transistor; and
a drain coupled to the gate of the tenth transistor.

14. The rail-to-rail input stage circuit as claimed in claim 13, wherein:
the sources of the sixth transistor, the seventh transistor, the eighth transistor, the thirteenth transistor, and the fourteenth transistor are coupled to a first power rail,
the sources of the second transistor, the third transistor, the fourth transistor, the eleventh transistor, and the twelfth transistor are coupled to a second power rail,
the first current source is coupled between the first power rail and the source of the first P-type transistor, and
the second current source is coupled between the source of the first N-type transistor and the second power rail.

15. An operational amplifier comprising:
an input stage circuit comprising:
a first current source providing a first current;
a second current source providing a second current;
a first P-type transistor coupled between the first current source and a first node and coupled to a first input terminal;
a second P-type transistor coupled between the first current source and a second node and coupled to a second input terminal;
a first N-type transistor coupled between the second current source and a third node and coupled to the first input terminal;
a second N-type transistor coupled between the second current source and a fourth node and coupled to the second input terminal;
a first processing circuit generating a third current based on a first control voltage in response to the voltage level of the first input terminal being higher than a first threshold value, wherein the sum of currents passing through the first N-type transistor and the second N-type transistor is equal to the sum of the first current and the third current;
a second processing circuit generating a fourth current based on a second control voltage in response to the voltage level of the first input terminal being lower than a second threshold value, wherein the sum of currents passing through the first P-type transistor and the second P-type transistor is equal to the sum of the second current and the fourth current;
a first voltage adjustment circuit adjusting the first control voltage in response to the voltage level of the first input terminal being higher than the first threshold value; and
a second voltage adjustment circuit adjusting the second control voltage in response to the voltage level of the first input terminal being lower than the second threshold value; and
an output stage circuit generating an output voltage based on voltage levels of the first node, the second node, the third node, and the fourth node.

16. The operational amplifier as claimed in claim 15, wherein:
the first processing circuit comprises a first compensation transistor and a first current mirror, the first compensation transistor is coupled to the first current source, and the first current mirror provides the third current based on the current passing through the first compensation transistor, and
the second processing circuit comprises a second compensation transistor and a second current mirror, the second compensation transistor is coupled to the second current source, and the second current mirror provides the fourth current based on the current passing through the second compensation transistor.

17. The operational amplifier as claimed in claim 16, wherein the first voltage adjustment circuit adjusts the voltage of the gate of the first compensation transistor based on the current passing through the first current mirror, and the second voltage adjustment circuit adjusts the voltage of the gate of the second compensation transistor based on the current passing through the second current mirror.

18. The operational amplifier as claimed in claim 17, wherein:
in response to the first voltage adjustment circuit adjusting the voltage of the gate of the first compensation transistor, the second voltage adjustment circuit stops adjusting the voltage of the gate of the second compensation transistor, and
in response to the second voltage adjustment circuit adjusting the voltage of the gate of the second compensation transistor, the first voltage adjustment circuit stops adjusting the voltage of the gate of the first compensation transistor.

19. The operational amplifier as claimed in claim 15, wherein the third current is three times the first current, the fourth current is three times the second current, and the first current is equal to the second current.

20. The operational amplifier as claimed in claim 15, wherein the output stage circuit comprises:
a first output transistor comprising a drain coupled to the third node;
a second output transistor comprising:
a source coupled to the third node; and
a drain coupled to the gate of the first output transistor;
a third output transistor comprising:
a drain coupled to the drain of the second output transistor; and
a source coupled to the second node;
a third current source coupled to the source of the third output transistor;
a fourth output transistor comprising:
a gate coupled to the gate of the first output transistor; and
a drain coupled to the fourth node; and
a fifth output transistor comprising:
a source coupled to the drain of the fourth output transistor;
a gate coupled to the gate of the second output transistor; and
a drain providing the output voltage.
